(19) United States
(12) Patent Application Publication
(10) Pub. No.: US 2008/0144686 A1
(43) Pub. Date: Jun. 19, 2008

(54) Surface emitting laser

(75) Inventors: Yoshinori Tanaka, Kyoto (JP); Masashi Yamamoto, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto (JP)

(21) Appl. No.: 12/000,660

(22) Filed: Dec. 14, 2007

(30) Foreign Application Priority Data
Dec. 15, 2006 (JP) P2006-338178

(51) Int. Cl. H01S 5/183

(52) U.S. Cl. 372/49.01

(57) ABSTRACT

A surface emitting laser includes an n-side multilayered reflection film and an active layer which are formed on a substrate. On the active layer, a mesa region is formed by sequentially stacking an AlGaAs current blocking layer, a p-side multilayered reflection film, a p-type contact layer and the like. A groove is formed to separate the mesa region from an outside region. The mesa region and the outside region are connected to each other with a beam portion provided in the groove. A reflection film with a high Al composition ratio in the p-side multilayered reflection film in the beam portion is completely oxidized, and thus has a high resistance.

### CROSS REFERENCE TO RELATED APPLICATIONS AND INCORPORATION BY REFERENCE

This application is based upon and claims the benefit of prior Japanese Patent Application P2006-338178 filed on Dec. 15, 2006; the entire contents of which are incorporated by reference herein.

### BACKGROUND OF THE INVENTION

1. Field of the Invention

The present invention relates to a vertical-cavity surface-emitting laser, and particularly to a surface emitting laser including a beam portion or bridge beam portion.

2. Description of the Related Art

A surface emitting laser which emits a laser light beam perpendicular to the semiconductor substrate is termed as a vertical-cavity surface-emitting laser (VCSEL). In the surface emitting laser, a p-n junction is formed by stacking GaAs, InGaAs and AlGaAs semiconductor thin films in the vertical direction. Thereafter, on the top and bottom of the p-n junction, two multiplayer reflector mirrors are formed, thus a resonant cavity is obtained. The surface emitting laser causes the resonant cavity to reflect light beams upward and downward many times, and emits resultant light beams whose phases meet each other.

It is said that surface emitting lasers have better characteristics than edge emitting lasers, such as lower threshold current, high efficiency and single horizontal mode operation. Recently, surface emitting lasers are put into practical use as array transmitters for optical communications. Practical use of surface emitting lasers is awaited in field other than the optical communications.

FIGS. 5 and 6 show an example of the structure of a conventional type of resin surface emitting laser. FIG. 5 is a plan view as viewed from above. FIG. 6 is a cross-sectional view taken along the line C-C of FIG. 5. An n-side multilayered reflection film 23 is formed on an n-type GaAs substrate 22 by alternately stacking n-type AlGaAs layers and n-type GaAs layers. An active layer 24 is stacked on the n-side multilayered reflection film 23. The active layer 24 has a quantum well structure obtained by stacking InGaAs and GaAs on one another.

As a mesa region 30, an AlAs current blocking layer 25, a p-side multilayered reflection film 26 and a p-type contact layer 27 are formed on the active layer 24. The p-side multilayered reflection film 26 is obtained by alternately stacking p-type AlGaAs layers and p-type GaAs layers. The p-type contact layer 27 is formed of p-type GaAs. Insulating resin 28 is embedded around the mesa region 30. A p-electrode 29 is provided covering a part of the top surface of the resin 28 and a part of the top surface of the p-type contact layer 27. In addition, an n-electrode 21 is formed on the bottom surface of the GaAs substrate 22. A portion between the n-side multilayered reflection film 23 and the p-side multilayered reflection film 26 constitutes a resonant cavity. This resonant cavity reflects light beams upward and downward many times, and generates resultant light beams whose phases meet each other. Thereby, a laser light beam is emitted through an opening portion 29A of the p-electrode 29.

Induced emission of a laser light beam requires a higher concentration of the laser light beam. To this end, it is necessary that an applied electrical current should be high in concentration. For the purpose of confining the spread of the electrical current to a narrower space, the current blocking layer 25 has a narrow AlAs portion which remains in its center formed by oxidizing the AlAs layer used as a row material for the current blocking layer 25 inward from its periphery. As a result of the oxidation process, the peripheral portion of the AlAs layer is turned into aluminum oxide. Because aluminum oxide is insulating, no electrical current flows in the peripheral portion. Electric current flows only in the center AlAs portion. The AlAs current blocking layer 25 has the narrow path of the electrical current which is obtained by oxidizing its peripheral portion in this manner. The current blocking layer 25 is termed as a current constriction layer in some cases.

The current blocking layer 25 is formed as follows. All the epitaxial layers are grown on the GaAs substrate 22. Subsequently, a part of the epitaxial layers is mesa-etched from the p-type contact layer 27 to at least the current blocking layer 25, and thereby the mesa region 30 is formed. Thereafter, steam is injected to the mesa region 30 with its side surface exposed to the outside. By this, the AlAs layer is heated, and is thus oxidized from its side surface. In contrast, the GaAs layer is not oxidized although the steam is injected thereto. Because a mixed crystal containing Ga but not Al is resistant to oxidation, the InGaAs layer, the GaAs layer and the like are hardly oxidized. After the AlAs layer is oxidized in an annular shape, the resin 28 is formed for the purpose of protecting the mesa region 30, and of evening off the resultant substrate for the forming of the p-electrode 29.

However, the current blocking layer 25 formed through oxidation in the foregoing manner shrinks in volume. This strains semiconductor layers on and under the current blocking layer 25. The current blocking layer 25 and the semiconductor layers thereon and thereunder are bonded so weakly that they are likely to suffer from defects such as dislocations and cracks due to thermal stress which is applied thereto in a heating process following the oxidation. These defects may possibly propagate to the active layer during the operation of the laser, thereby causing non-light emitting area. The resin surface emitting laser has a problem that the reliability and properties thereof are deteriorated when the non-light emitting area is caused in the foregoing manner.

For the purpose of solving the problem, proposed is a structure which, unlike the structure of the resin surface emitting laser, aims at preventing defects such as cracks from being caused due to thermal stress by partially bonding the mesa region and its outside region by forming a beam portion or bridge beam portion, as disclosed, for example, in Japanese Patent Application Laid-open Publication No. 2006-216722.

Indeed, the foregoing prior art contributes to preventing defects such as cracks from being caused due to thermal stress by partially bonding the mesa region and its outside region. However, the prior art brings about a problem that the threshold current for laser oscillation becomes higher, because electrical current (leakage current) flows outward through the bonding part between the mesa region and its outside region so that the leakage current turns into a reactive current that does not contribute to the light emission.

The present invention has been made for the purpose of solving the problem. An object of the present invention is to provide a surface emitting laser including a beam portion, in which a leakage current is reduced to a large extent, and whose current threshold value for its laser oscillation is accordingly lowered.

### SUMMARY OF THE INVENTION

A first aspect of the present invention is a surface emitting laser characterized by including multilayered reflection films, a mesa region, an outside region and a beam portion. The multilayered reflection films constitute a part of a resonant cavity, and each multilayered reflection film is formed with a multilayered structure including reflection films whose Al composition ratios are different from one film to another. The mesa region includes at least one of the multilayered reflection films. The outside region surrounds the mesa region with a groove interposed inbetween. The beam portion connects the mesa region to the outside region, and includes at least one of the multilayered reflection films. In the beam portion, a reflection film with the highest Al composition ratio in the multilayered reflection film is completely oxidized.

A second aspect of the present invention is the surface emitting laser according to the first aspect, characterized in that a contact layer is formed between an electrode and the multilayered reflection film arranged at the side through which a laser light beam is emitted, in the mesa region.

A third aspect of the present invention is the surface emitting laser according to the first aspect, characterized in that a layer structure of the beam portion is the same as that of the outside region.

A fourth aspect of the present invention is the surface emitting laser according to the second aspect, characterized in that a layer structure of the beam portion is the same as that of the outside region.

A fifth aspect of the present invention is the surface emitting laser according to the first aspect, characterized in that the beam portion is formed in a single location or a plurality of locations.

A 6th aspect of the present invention is the surface emitting laser according to the second aspect, characterized in that the beam portion is formed in a single location or a plurality of locations.

A 7th aspect of the present invention is the surface emitting laser according to the third aspect, characterized in that the beam portion is formed in a single location or a plurality of locations.

A reflection film whose Al composition ratio is the highest among the Al composition ratios of the respective reflection films in a multilayered reflection film formed in the beam portion connecting the mesa region to the outside region, which is one of the multilayered reflection films constituting the laser resonant cavity, is a completely-oxidized structure. For this reason, the beam portion has a high resistance, and electrical current is accordingly less likely to leak to the outside region. This makes it possible to reduce a leakage current to a large extent, and accordingly to lower a current threshold value for laser oscillation.

### BRIEF DESCRIPTION OF THE DRAWINGS

FIG. 1 is a plan view of a surface emitting laser according to the present invention, which is viewed from above.

FIG. 2 is a cross-sectional view of the surface emitting laser taken along the line A-A of FIG. 1.

FIG. 3 is a cross-sectional view of the surface emitting laser taken along the line B-B of FIG. 1

FIG. 4 is a diagram showing a comparison of threshold current of laser oscillation between the case where reflection films with a high Al composition ratio in a multilayered reflection film in each beam portion are completely oxidized with various numbers of beam portions, and the case where the reflection films are not completely oxidized.

FIG. 5 is a plan view of a conventional type of resin surface emitting laser.

FIG. 6 is a cross-sectional view of the conventional type of resin surface emitting laser taken along the line C-C of FIG. 5.

### DETAILED DESCRIPTION OF THE INVENTION

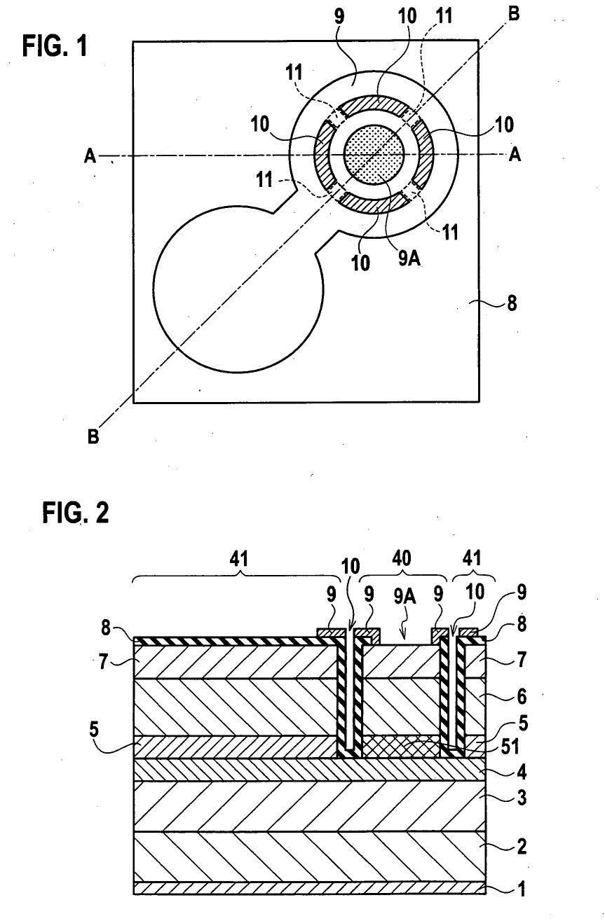

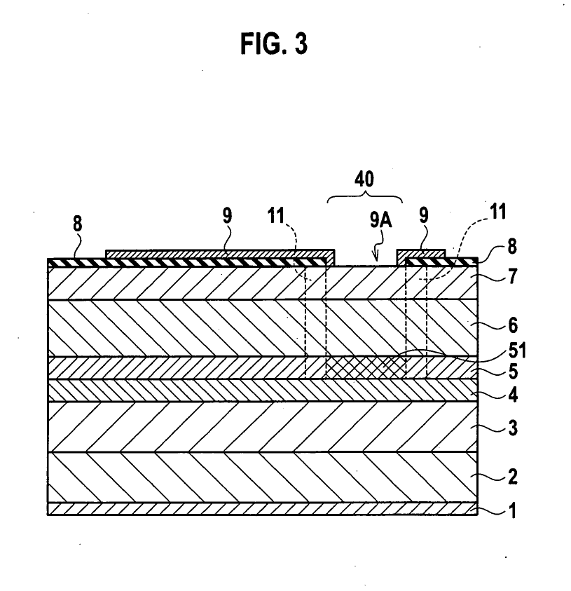

Descriptions will be provided hereinbelow for an embodiment of the present invention with reference to the drawings. FIG. 1 is a top view of a surface emitting laser according to the present invention, which is viewed from the side through which a laser light beam is emitted. FIG. 2 shows a cross-sectional structure of the surface emitting laser taken along the line A-A of FIG. 1. FIG. 3 shows a cross-sectional structure of the surface emitting laser taken along the line B-B of FIG. 1.

The surface emitting laser includes an n-side multilayered reflection film 3 and an active layer 4 which are formed on a substrate 2. On the active layer 4, a virtually columnar mesa region 40 is formed by sequentially stacking an Alₓ₃GaAs current blocking layer 51, a p-side multilayered reflection film 6, a p-type contact layer 7 and the like.

A virtually annular groove 10 separates the mesa region 40 from an outside region 41. The mesa region 40 is surrounded by the outside region 41 with the groove 10 interposed therebetween. The mesa region 40 and the outside region 41 is connected to each other with beam portions 11 (regions indicated by broken lines in FIGS. 1 and 3) provided to the groove 10.

The outer region 41 is configured of the Al_{X3}GaAs current blocking layer 51, the p-side multilayered reflection film 6, and the p-type contact layer 7 and the like. The layer structure of the outer region 41 is almost as the same as that of the mesa structure 40. However, the current blocking layer 51 includes a high-resistance region formed by oxidizing an AlGaAs layer. Note that, it is desirable that the groove 10 should be deep enough for the current blocking layer 51 to be fully exposed at the sidewalls of the groove 10 so that the high-resistance region can be formed in the current blocking layer 51 in the mesa region 41 in a manufacturing step, which will be described later.

On the surface of each of the mesa region 40, the outside region 41, and the beam region 11, an insulating film 8 made of SiO₂ (silicon oxide), SiN (silicon nitride) or the like is formed. The substrate 2 is made of an n-type GaAs substrate. The active layer 4 has a quantum well structure, in which a well layer is sandwiched between barrier layers whose bandgaps are larger than that of the well layer. The number of quantum well structures is not necessarily limited to one. Multiple quantum wells may be included in the active layer 4. In this case, the active layer has a multi quantum well (MQW) structure.

The active layer 4 is formed, for example, with a multi quantum well structure in which a non-doped InGaAs well layer and a non-doped GaAs barrier layer are alternately stacked on each other. The Alₓ₃GaAs current blocking layer 51 is made, for example, of Al_{0.98}GaAs (where x3=0.98) which contains Ga in a very small composition ratio. The current blocking layer 51 has an annular high-resistance region, which is formed by oxidizing an AlGaAs layer, around a low-resistance region made of AlGaAs. This configuration causes the electrical current to be constricted into the low-resistance region only. A region corresponding to the low-resistance region, in the active layer 4 serves as a light emitting region.

A portion between the n-side multilayered reflection film 3 and the p-side multilayered reflection film 6 constitutes a resonant cavity. The n-side multilayered reflection film 3 is a distributed Bragg reflector (DBR) mirror with a multilayered structure, which is made of n-type AlGaAs mixed crystal. The p-side multilayered reflection film 6 is also a DBR mirror with a multilayered structure, which is made of p-type AlGaAs mixed crystal.

A DBR mirror has reflecting surfaces which are laminated at certain intervals so that a light beam with a particular wavelength that is incident at a specific angle can satisfy the Bragg reflection condition. The DBR mirror magnifies the intensity of reflected light by use of interference between the reflected light beams in order to attain a higher reflectance.

The n-side multilayered reflection film 3 is configured of first and second reflection films. The first reflection film serving as a film with a high Al composition ratio is made of n-type Al_{X1}GaAS. The second reflection film serving as a film with a low Al composition ratio is made of n-type Al_{X2}GaAS (X1>X2). For example, the n-side multilayered reflection film 3 is made of n-type Al_{0.92}GaAs (the films with a high Al composition ratio) and n-type Al_{0.16}GaAs (the films with a low Al composition ratio). The n-side multilayered reflection film 3 is formed by alternately stacking an n-type Al_{0.92}GaAs layer and an n-type Al_{0.16}GaAs layer, for example, 40 times on the substrate 2.

In addition, the p-side multilayered reflection film 6 is configured of third and fourth reflection films. The third reflection film serving as a film with a high Al composition ratio is made of p-type Al_{Y1}GaAs. The fourth reflection film serving as a film with a low Al composition ratio is made of p-type Al_{Y2}GaAs (Y1>Y2). For example, the p-side multilayered reflection film 6 is made of p-type Al_{0.92}GaAs (the films with a high Al composition ratio) and p-type Al_{0.l6}GaAs (the films with a low Al composition ratio). The p-side multilayered reflection film 6 is formed by alternately stacking a p-type Al_{0.92}GaAs layer and a p-type Al_{0.16}GaAs layer, for example, 20 to 25 times on the current blocking layer 51 or the AlGaAs layer 5.

For example, the n-side multilayered reflection film 3 utilizes interference phenomena between light beams reflected off multiple interfaces constituted of the first and second reflection films. The phases of the light beams respectively reflected off the different interfaces are shifted by 360 degrees, and thus the intensities of the light beams are magnified to a great extent by causing the light beams to constructively interfere with one another. In this respect, the thicknesses of the first and second reflection films for making the n-side multilayered reflection film 3 work in the foregoing manner are respectively defined as λ/n1 and λ/n2, where n1 and n2 denote the refractive indices of the first and second reflection films, respectively, and λ denotes the wavelength of a laser light beam which is intended to be oscillated in the resonant cavity. The same holds for the third and fourth reflection films in the p-side multilayered reflection film 6.

The beam portion 11 connects the mesa region 40 and the outside region 41, and prevents the mesa region 40 from being separated from the active layer 4 due to thermal stress in the manufacturing process. FIG. 1 shows four beam portions 11. However, the number of beam portions 11 is not limited to this. In addition, the intervals at which the beam portions are provided, or the shapes of the beam portions are not limited to those shown in FIG. 1. Beam portions may be provided in a spiral pattern instead of in the radial pattern shown in FIG. 1. The layer structure of each beam portion 11 is the same as that of the outside region 41.

The p-type contact layer 7 is formed commonly in the outside region 41, the beam portions 11, and the mesa region 40. In addition, the third reflection films serving as the film with a high Al composition ratio in the p-side multilayered reflection film 6 in each beam portion 11 is oxidized completely, and thus has a high resistance.

It is desirable that the p-type contact layer 7 should be made, for example, of p-type GaAs. In a regular type of surface emitting laser, an AlGaAs mixed-crystal layer with a low Al composition ratio in its p-type multilayered reflection film 26 serves as a contact layer. Compared with this, the p-type contact layer 7 made of p-type GaAs containing no aluminum makes it possible to lower the contact resistance of a p-electrode 9.

The p-electrode 9 is formed on the p-type contact layer 7. This p-electrode 9 is formed in a shape continuing from the p-type contact layer 7 to the outside region 41 via the beam portions 11. For this reason, the p-electrode 9 has no step and accordingly no risk of discontinuity. In addition, an opening portion 9A is formed in the p-electrode 9, which is provided to the side through which the laser light beam is emitted. This is because the p-electrode 9 would otherwise absorb the laser light beam. On the other hand, an n-electrode 1 is formed on the back surface of the substrate 2. Mg or the like is used as a dopant for making the p-electrode, and Si or the like is used as a dopant for making the n-electrode.

Descriptions will be provided hereinbelow for a method of manufacturing a surface emitting laser configured in the foregoing manner. First of all, on the substrate 1 made of the foregoing material, the n-side multilayered reflection film 3, the active layer 4, the AlGaAs layer 5 later used as the current blocking layer 51, the p-side reflection film 6 and the p-type contact layer 7 are epitaxially grown sequentially by metal organic chemical vapor deposition (MOCVD) method or the like.

After growing the p-type contact layer 7, a resist mask is selectively formed on the p-type contact layer 7. Subsequently, the p-type contact layer 7, the p-side multilayered reflection film 6, the AlGaAs layer 5 and the active layer 4 are selectively removed by mesa-etching. Thereby, the groove 10 is formed to separate the mesa region 40 and the outside region 41 from each other. Simultaneously, the beam portions are formed.

After forming the groove 10 and the beam portions, the AlGaAs layer 5 exposed to the groove 10 and the layers with the high Al composition ratio (p-type Al_{0.92}GaAs layers in the above-described example) in the p-side multilayered reflection film 6 constituting the beam portions 11 are oxidized, for instance, by heating in steam. The oxidation of the AlGaAs layer 5 in the mesa region 40 progresses from its peripheral toward its center. On the other hand, the oxidation of each of the layers with the high Al composition ration in the p-side multilayered reflection film 6 in each beam portion 11 progresses from its two sides, because the two sides of each of the layers with the high Al composition ratio are exposed to the groove 10. By terminating the oxidation at an appropriate time, an annular high-resistance region is formed and the center portion remaining unoxidized is set as a low-resistance region. Thereby, the current blocking layer 51 with its low-resistance region surrounded by the high-resistance region is formed in the AlGaAs layer 5 while the layers with the high Al composition ratio in the p-side multilayered reflection film 6 constituting the beam portions 11 are completely oxidized.

For the current blocking layer 51 Alₓ₃GaAs instead of AlAs is used herein. The current blocking layer 51 used here is a film with a oxidation rate adjusted such that the layers with the high Al composition ratio in the p-side multilayered reflection film 6 constituting each beam portion 11 are completely oxidized before the diameter of the oxidized part of the current blocking layer 51 becomes equal to a desired oxidation diameter. Specifically, to adjust the oxidation rate, the current blocking layer 51 is formed by adding a slight amount of Ga to AlAs or made to have an adjusted thickness. In addition, the oxidation rate can be adjusted by changing the diameter of the mesa region 40 and the width of the beam portions 11.

The current blocking layer 51 and the layer with the high Al composition ratio in the p-side multilayered reflection film 6 constituting each beam portion 11 are heated at 450° C., for instance, by introduced the steam thereto from the groove 10 with a flow rate of 1 cc/minute in order to make the oxidation diameter of the current blocking layer 51 equal to the desired oxidation diameter, and concurrently to completely oxidize the layers with the high Al composition ratio. In addition, each beam portion 11 is formed to have a width (the difference between its external diameter and its internal diameter) of 3 μm to 4 μm.

After forming the current blocking layer 51, the insulating film 8 made of the above-described material is removed except for its part corresponding to the opening portion 9A. Thereafter, the n-electrode 1 is formed on the back surface of the substrate 2 by deposition, sputtering or the like. Subsequently, the p-electrode 9 is formed ranging from a part of the top of the p-type contact layer 7 and a part of the top of the insulating films except for the part of the insulating film 8 which corresponds to the opening portion 9A. The surface emitting laser shown in FIGS. 1 to 3 is completed in this manner.

In this type of surface emitting laser, once a predetermined voltage is applied between the n-electrode 1 and the p-electrode 9, a driving current supplied from the p-electrode 9 is constricted by the current blocking layer 51, and is thereafter applied to the active layer 4. Thereby, a light beam is generated. The light beam is reflected by the p-side multilayered reflection film 6 and the n-side multilayered reflection film, and reciprocates between the two films 3 and 6, thus causing the laser oscillation. Thereafter, as a laser light beam, the light beam is emitted to the outside through the opening portion 9A. In this respect, because the layers with the high Al composition ratio in the p-side multilayered reflection film 6 in each beam potion 11 is completely oxidized to have high resistance, these layers checks the electrical current from leaking out from the p-type contact layer 7 to the outside region 41 through the beam portions 11.

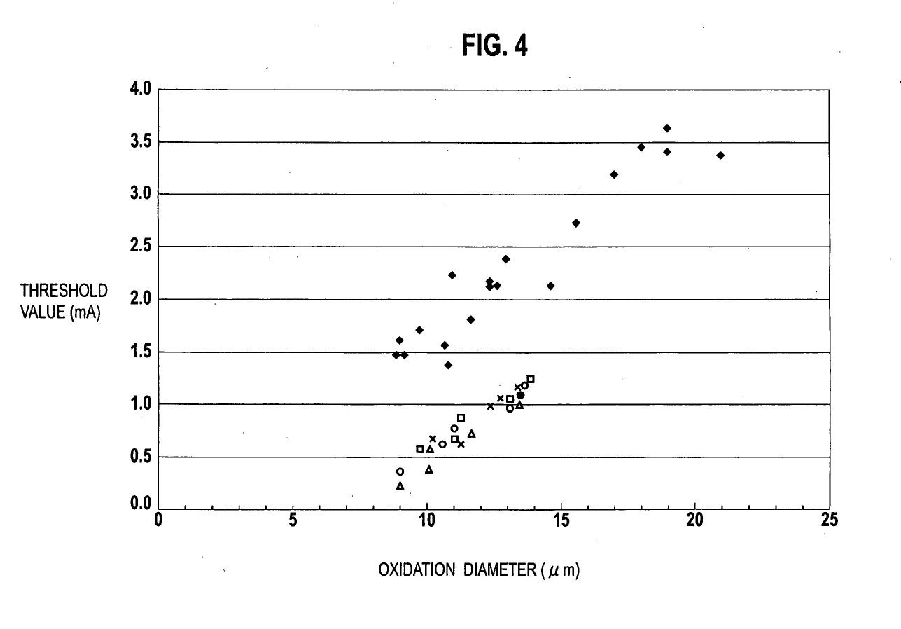

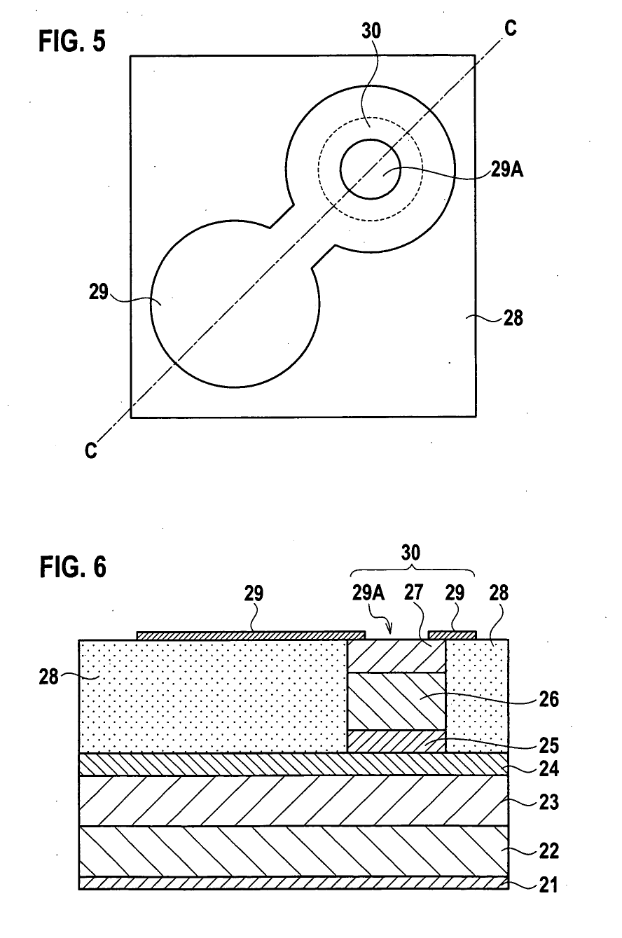

FIG. 4 shows a comparison between the case where AlGaAs layers with the high Al composition ratio in the multilayered reflection film in each beam portion 11 were oxidized completely in the foregoing manner, and the case where the AlGaAs layers with the high Al composition ratio were not oxidized completely. In this figure, a filled diamond symbol (♦) denotes a surface emitting laser having four beam portions which were not oxidized completely; an open square (□) , a surface emitting laser having four beam portions which were oxidized completely; × symbol, a surface emitting laser having three beam portions which were oxidized completely; an open circle (∘),a surface emitting laser having two beam portions which were oxidized completely; an open triangle (Δ) ,a surface emitting laser having one beam portion which was oxidized completely; and a filled circle (), the resin surface emitting laser as shown in FIGS. 5 and 6.

As is clear from the figure, data on the surface emitting laser (♦) whose beam portions were not completely oxidized indicate that the threshold value of its laser oscillation current was considerably high whereas data on the surface emitting lasers (□, × and ∘) whose beam portions were completely oxidized indicate that the threshold values of their respective laser oscillation currents were lower regardless of the number of beam portions. In addition, each of the surface emitting lasers whose beam portions were completely oxidized was capable of lowering the threshold value of its laser oscillation current almost to the threshold value of the laser oscillation current of the resin surface emitting laser.

It goes without saying that the present invention includes its various examples and the like which have not been described here. The technical scope of the present invention shall be defined by the following claims which are considered as being appropriate judging from the foregoing descriptions.

What is claimed is:

1. A surface emitting laser comprising:
multilayered reflection films constituting a part of a resonant cavity, each multilayered reflection film formed with a multilayered structure including reflection films whose Al composition ratios are different from one film to another;
a mesa region including at least one of the multilayered reflection films;
an outside region surrounding the mesa region with a groove interposed inbetween;
a beam portion connecting the mesa region to the outside region, and including at least one of the multilayered reflection films, wherein
in the beam portion, a reflection film with the highest Al composition ratio in the multilayered reflection film is completely oxidized.

2. The surface emitting laser of claim 1, wherein
in the mesa region, a contact layer is formed between an electrode and the multilayered reflection film arranged at the side through which a laser light beam is emitted.

3. The surface emitting laser of claim 1, wherein
a layer structure of the beam portion is the same as that of the outside region.

4. The surface emitting laser of claim 2, wherein
a layer structure of the beam portion is the same as that of the outside region.

5. The surface emitting laser of claim 1, wherein
the beam portion is formed in a single location or a plurality of locations.

6. The surface emitting laser of claim 2, wherein
the beam portion is formed in a single location or a plurality of locations.

7. The surface emitting laser of claim 3, wherein
the beam portion is formed in a single location or a plurality of locations.
